(19) United States
(12) Patent Application Publication
(10) Pub. No.: US 2007/0152724 A1
(43) Pub. Date: Jul. 5, 2007

(54) Reset circuit and electrical device with the reset circuit providing a reset signal during power changing status

(75) Inventors: Kuo-Ting Chiu, Taipei City (TW); Yu-Huei Cheng, Taipei City (JP); Tzu-Hui Lee, Taipei City (TW)

Correspondence Address: BACON & THOMAS, PLLC, 625 SLATERS LANE, FOURTH FLOOR, ALEXANDRIA, VA, 22314, US

(73) Assignee: Tatung Company, Taipei City (TW)

(21) Appl. No.: 11/437,723

(22) Filed: May 22, 2006

(30) Foreign Application Priority Data
Dec. 29, 2005 (TW) 094147207

(51) Int. Cl. H03K 3/02

(52) U.S. Cl. 327/198

(57) ABSTRACT

An electrical device with a reset circuit providing a reset signal during power changing status is disclosed. The present invention comprises a power circuit, a micro control unit, a first reset circuit, a microprocessor, and a second reset circuit. The micro control unit has a reset pin and as it receives voltage from the power circuit, the micro control unit performs a reset operation. The first reset circuit is connected to the power circuit for providing a level signal. The microprocessor has a reset pin and is connected to the power circuit, and as the reset pin receives a level signal the microprocessor performs the reset operation. The second reset circuit is connected to the power circuit and has a reset pin of microprocessor for providing a level signal.

### BACKGROUND OF THE INVENTION

1. Field of the Invention

The present invention relates to a reset circuit and, more particularly, to a reset circuit used to provide a reset signal during power change status, and an electrical device having the reset circuit.

2. Description of Related Art

Currently, electrical devices commonly use a reset circuit to perform a reset operation during power on status for starting the element of electrical device. In reference to FIG. 1, a prior art of the reset circuit comprises a power circuit 100, a micro control unit 500, and a reset circuit 300, wherein the power circuit is used to supply power to the micro control unit 500 and the reset circuit 300.

The micro control unit 500 is electrically connected to the power circuit 100, wherein the micro control unit 500 comprises a reset pin 510. As the reset pin 510 receives an input terminal trigger, the micro control unit 500 begins performing a reset operation.

The reset circuit comprises a Zener diode 400, a transistor 700, a capacitor 800, and a resistor-capacitor circuit 600, wherein the Zener diode 400 is electrically connected to a base end of the transistor 700, the base B and emitter E of transistor 700 are electrically connected to a capacitor, and the collector C of transistor 700 is connected to the reset pin 510 of micro control unit 500.

As the power circuit 100 becomes powered on, the power circuit 100 supplies power to emitter E of the transistor 700, and at this time, the capacitor 800 becomes short immediately, whereby the power circuit 100 supplies voltage to the Zener diode 400 through a resistor. Before the Zener diode 400 reaches a break down voltage, the transistor 700 still cannot operate, therefore, the voltage connected to the reset pin 510 of the micro control unit 500 is a low voltage (low level) used to enable the micro control unit 500 to perform the reset operation.

After a while, when the Zener diode 400 reaches a break down voltage, the transistor 700 begins operating. Therefore, the voltage connected to the reset pin 510 of the micro control unit 500 becomes a high voltage (high level) so as to stop generating the reset signal.

From the above-mentioned, the reset circuit 300 used to send a trig signal to the micro control unit 500 for triggering the reset pin 510 to perform the reset operation. In fact, the reset circuit 300 performs the reset without considering a problem of time sequence in the process of power changing status. So as an electrical device uses another reset circuit to reset a microprocessor (not shown in fig), due to different charging and discharging time of capacitor 800 between two reset circuits 300, asynchronous operation easily occurs during processing reset of the micro control unit and microprocessor.

Therefore, it is desirable to provide an improved circuit to mitigate and/or obviate the aforementioned problems.

### SUMMARY OF THE INVENTION

The object of the present invention is to provide a reset circuit and an electrical device using the reset circuit, such that by using the reset circuit, this present invention will provide high and low level signal simultaneously for enabling a microprocessor and micro control unit to perform a reset operation.

To achieve the object, the electrical device of the present invention comprises a power circuit for outputting a voltage; a micro control unit connecting to said power circuit, and said micro control unit comprising a reset pin whereby when said reset pin receives a first level signal, said micro control unit performs a reset operation; a first reset circuit electronically connecting to said power circuit and said reset pin of said micro control unit providing a first level signal; a microprocessor electronically connecting to said power circuit for receiving power and said microprocessor comprising a reset pin, whereby when said reset pin receiving a second level signal, said microprocessor performs a reset operation; and a second reset circuit electronically connecting to said power circuit and said reset pin of said microprocessor providing a second level signal; wherein, as said power circuit changes to power on status said power circuit begins supplying power to said first reset circuit and said second reset circuit, said first reset uses the power providing said first level signal for resetting said micro control unit and said second reset circuit being driven by said first reset circuit providing said second level signal to reset said microprocessor.

To achieve the object, the reset circuit of the present invention receives voltage from a power circuit, thereby enabling a reset pin of the micro control unit and microprocessor, to perform a reset operation, the reset circuit comprising; a first reset circuit, comprising: a Zener diode comprising an anode electrically connected to said power circuit and a cathode electrically connected to the ground; a first transistor comprising an emitter, a base, and a collector, said base electrically connected to said anode of said Zener diode, said collector connected to said reset pin of said micro control unit through an R-C circuit (resistor capacitor), a capacitor connected between said emitter and said base of said transistor, wherein as said power circuit, said power circuit supplies power to said Zener diode providing a low level signal output to said reset pin of said micro control unit to enable said micro control unit perform a reset operation, as said Zener diode begins operating, said Zener diode uses said first transistor to provide a high level signal for outputting to said reset pin of said micro control unit, so as to control said micro control unit to stop performing reset; and a second reset circuit, comprising a second transistor having a base, an emitter, and a base, said emitter connected to said power circuit, said collector connected to said reset pin of said microprocessor, the base connected to said collector of said first transistor through a resistor, wherein as said power circuit begins operating and supplying power to said transistor, the transistor used to provide a high level reset signal and output to said reset pin of said microprocessor for enabling said microprocessor to perform the reset.

Other objects, advantages, and novel features of the invention will become more apparent from the following detailed description when taken in conjunction with the accompanying drawings.

### BRIEF DESCRIPTION OF THE DRAWINGS

FIG. 1 is a schematic drawing illustrating an embodiment of reset circuit of the prior art; and

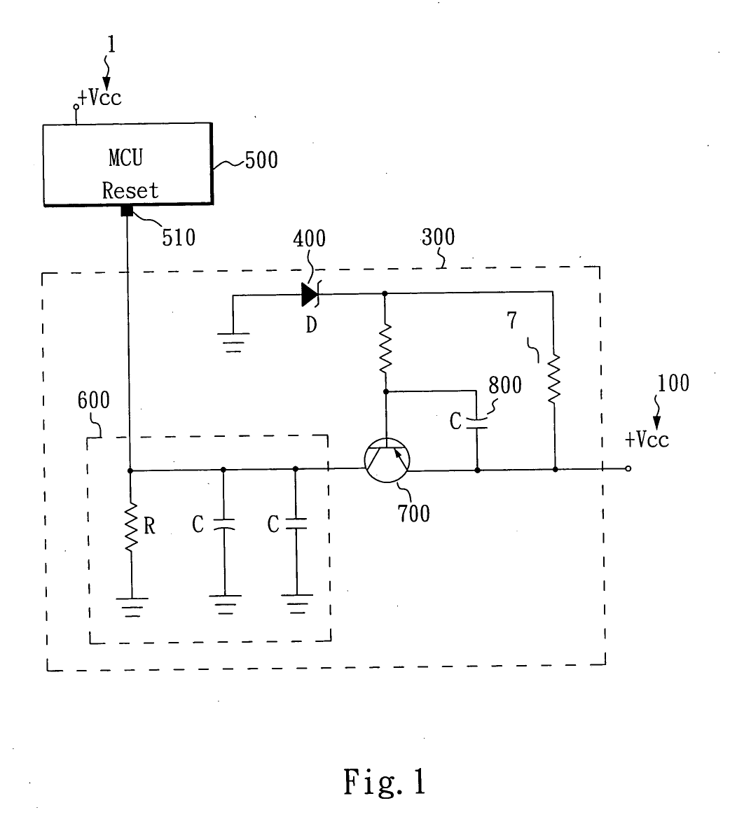

FIG. 2 is a schematic drawing showing an embodiment of a reset circuit according to the present invention.

### DETAILED DESCRIPTION OF THE PREFERRED EMBODIMENT

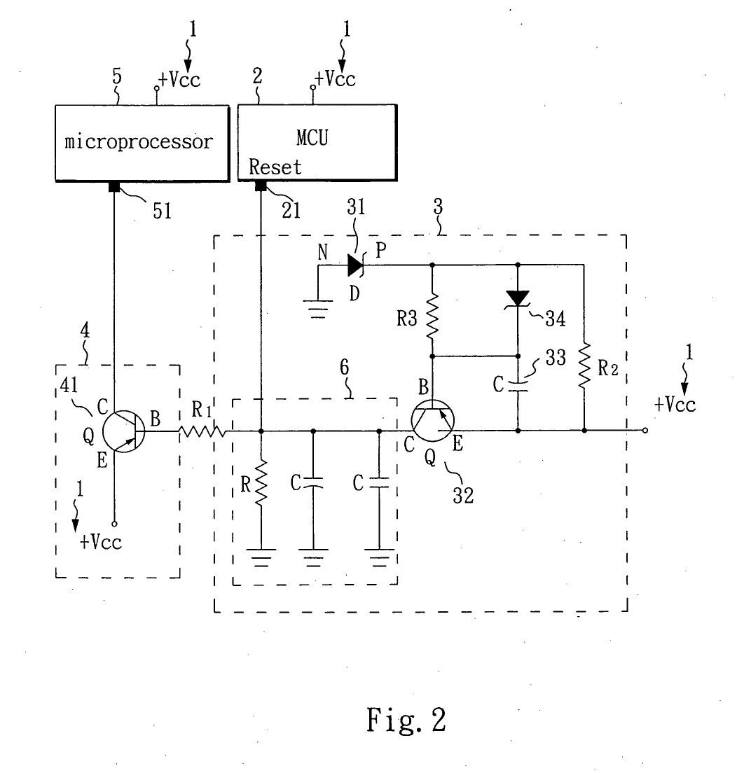

FIG. 2 shows a block diagram for a preferred embodiment of the present invention. This embodiment comprises a power circuit 1, a micro control unit 2, a first reset circuit 3, a second reset circuit 4, and a microprocessor 5. Wherein, when the electrical device becomes powered on, power circuit 1 will begin to supply power to the micro control unit 2, the first reset circuit 3, the second reset circuit 4, and microprocessor 5. The micro control unit 2 is electrically connected to the power circuit 1, and the micro control unit 2 comprises a reset pin 21. When the reset pin 21 receives a low level signal, the micro control unit 2 will perform a reset operation. The first reset circuit 3 is connected to the power circuit 1 and the reset pin 21 of micro control unit providing a low level signal.

The microprocessor 5 is electrically connected to the power circuit 1 and the microprocessor comprises a reset pin 51. When the reset pin 51 receives a high level signal the microprocessor 5 will perform a reset operation. The second reset circuit 4 is electrically connected power circuit 1 and reset pin 51 of the microprocessor 5 providing a high level signal.

As the power circuit becomes powered on the second reset circuit is used to enable the reset pin 51 of microprocessor for performing a reset operation, wherein the second circuit 4 comprises a transistor 41 having a collector C, an emitter E and a base B. The emitter E is connected to the power circuit 1, the collector C is connected to reset pin 51 of the microprocessor 51, and the base B is connected to collector C of the first transistor of the first reset circuit 3 through a resistor (R1). When the power circuit becomes powered on, the transistor 41 will output a high level signal to the reset pin 51 of the microprocessor 5 for enabling microprocessor 5 to perform a reset operation.

The first rest circuit comprises two Zener diodes 33,34, a transistor 32, a capacitor 33 and a resistor-capacitor circuit 6(R-C). Wherein, the Zener diode comprising an anode P is electrically connected to said power circuit and a cathode N is electrically connected to the ground; the transistor 32 comprises an emitter E, a base B and a collector C, the emitter E is connected to the power circuit 1, the base B is connected to the reset pin 21 of said micro control unit 2 through the resistor-capacitor circuit 6. The capacitor 33 is connected between the emitter E and base B of the transistor 32. When the power circuit 1 is in the powered on status, the transistor 32 will stop operating, and the power circuit 1 supplies power to the Zener diode 31 providing a low level signal output to the reset pin 21 of the micro control unit 2 for enabling the micro control unit 2 to perform a reset operation. In addition, the power circuit 1 supplies voltage to the Zener diode 31, and as the Zener diode 31 reaches a break down voltage the Zener diode 31 begins operating and supplying voltage transistor 32 thereby providing a high level reset signal and output to the reset pin 21 of the micro control unit 2 for terminating generation of the reset signal.

The Zener diode 34 is used to prevent reverse current flowing into the transistor 32.

In FIG. 2, as the power circuit 1 becomes powered on the power circuit 1 supplies voltage to the first reset circuit 3 and the second reset circuit 4. At this time, the capacitor 33 of the first reset circuit 3 becomes short immediately; the power circuit 1 supplies voltage to the Zener diode 31 through a resistor (R2), and performs charging at the capacitor 33 through the Zener diode 34 for saving power. Due to the transistor 32 still not operating, the voltage connected to the reset pin 21 of micro control unit 21 is low level for enabling the micro control unit 2 to perform a reset operation. At the same time, the transistor 41 of the second reset circuit 4 is still operating, thus the voltage connected to the reset pin 51 of microprocessor 5 is high level voltage, the high level voltage used to enable the microprocessor to perform a reset operation. After a while, the Zener diode begins operating as the diode 31 reaches break down voltage. The emitter E and the base B of transistor 32 will provide a voltage difference (more than 0.7V) for starting the transistor, and the voltage connected to the reset pin 21 of micro control unit 2 is a high level voltage, used to stop generation of the reset signal for the microprocessor 5.

Said power circuit supplying power to said Zener diode 31 provides a low level signal output to said reset pin of said micro control unit to enable said micro control unit perform a reset operation, and as said Zener diode begins operating said Zener diode uses said first transistor to provide a high level signal for outputting to said reset pin of said micro control unit, so as to control said micro control unit to stop performing reset.

From the above-mentioned, this present invention not only prevents reset timing asynchronous operation. Between the micro control unit and microprocessor, but also supplies different level signal (high and low level signal) for performing a reset operation.

Although the present invention has been explained in relation to its preferred embodiment, it is to be understood that many other possible modifications and variations can be made without departing from the spirit and scope of the invention as hereinafter claimed.

What is claimed is:

1. An reset circuit and electrical device with the reset circuit providing a reset signal during power charging status, comprising;
a power circuit for outputting a voltage;
a micro control unit connecting to said power circuit, and said micro control unit comprising a reset pin, as said reset pin receives a first level signal, said micro control unit performs a reset operation;
a first reset circuit connecting to said power circuit and said reset pin of said micro control unit, said first reset circuit providing a first level signal;
a microprocessor connecting to said power circuit for receiving electrical power and said microprocessor comprising a reset pin, as said reset pin receiving a second level signal, said microprocessor performs reset operation; and
a second reset circuit connecting to said power circuit and said reset pin of said microprocessor, said first reset circuit providing a second level signal;
wherein, as said power circuit changes to a power on status, said power circuit begins supplying power to said first reset circuit and said second reset circuit, said first reset uses the power providing said first level signal for resetting said micro control unit and said second reset circuit being driven by said first reset circuit providing said second level signal to reset said microprocessor.

2. The electrical device as claimed in claim 1, wherein said first reset circuit further comprising:
a Zener diode comprising an anode electrically connected to said power circuit and a cathode electrically connected to the ground;
a first transistor comprising an emitter, a base and a collector, said emitter connected to said power circuit, said base connected to said reset pin of said micro control unit through a resistor-capacitor circuit; and
a capacitor connected between said emitter and said base of said transistor.

3. The electrical device as claimed in claim 1, wherein said second reset circuit further comprising;
a second transistor comprising an emitter, a base and a collector, said emitter connected to said power circuit, said collector connected to said reset pin of said microprocessor, the base connected to said collector of said first transistor through a resistor.

4. The electrical device as claimed in claim 1, wherein said second level signal is a high level signal, said reset pin of said microprocessor being triggered by a high level signal.

5. The electrical device as claimed in claim 1, wherein said first level signal is a low level signal, and said reset pin of said micro control unit being triggered by a low level signal.

6. A reset circuit providing a reset signal during power changing status, said reset circuit receives voltage from a power circuit to enable a reset pin of a micro control unit and a microprocessor for controlling said micro control unit and said microprocessor to perform a reset operation, the reset circuit comprising;
a first reset circuit, comprising;
a Zener diode comprising an anode electrically connected to said power circuit and a cathode electrically connected to the ground;
a first transistor comprising an emitter, a base, and a collector, said base electrically connected to said anode of said Zener diode, said collector connected to said reset pin of said micro control unit through a resistor-capacitor circuit;
a capacitor connected between said emitter and said base of said transistor, wherein as said power circuit changes to a power on status, said power circuit supplies power to said Zener diode providing a low level signal output to said reset pin of said micro control unit to enable said micro control unit to perform reset operation, as said Zener diode begins operating said Zener diode uses said first transistor to provide a high level signal for outputting to said reset pin of said micro control unit, so as to control said micro control unit to stop performing reset; and
a second reset circuit, comprising a second transistor having a base, an emitter, and a base, said emitter connected to said power circuit, said collector connected to said reset pin of said microprocessor, the base connected to said collector of said first transistor through a resistor, wherein as said power circuit begins operating and supplying power to said transistor, said transistor used to provide a high level reset signal and output to said reset pin of said microprocessor for enabling said microprocessor to perform the reset.
